(19) United States
(12) Patent Application Publication
(10) Pub. No.: US 2021/0016489 A1
(43) Pub. Date: Jan. 21, 2021

(54) REPLICA FILM OF REAL MATERIAL, METHOD FOR PRODUCING SAME, AND AUTOMOTIVE PART COMPRISING SAME

(71) Applicants: Hyundai Motor Company, Seoul (KR); Kia Motors Corporation, Seoul (KR)

(72) Inventors: Jae Sik SEO, Hwaseong-si (KR); Hyun Jung KIM, Hwaseong-si (KR); Ho Tak JEON, Hwaseong-si (KR)

(73) Assignees: Hyundai Motor Company, Seoul (KR); Kia Motors Corporation, Seoul (KR)

(21) Appl. No.: 16/677,297

(22) Filed: Nov. 7, 2019

(30) Foreign Application Priority Data
Jul. 15, 2019 (KR) 10-2019-0085052

(51) Int. Cl. B29C 59/02; B29C 59/00; B32B 3/26; B32B 27/08; B44F 9/00

(52) U.S. Cl. CPC B29C 59/022; B29C 59/026; B29C 59/005; B29L 2031/3005; B32B 27/08; B44F 9/00; B32B 3/26

(57) ABSTRACT

The present disclosure relates to a replica film of a real material, a method for producing the same, and an automotive part comprising the same. In detail, the replica film of a real material may include: a base material layer; and a resin layer disposed on the base material layer, having a first surface facing the base material layer and a second surface, opposite the first surface, having the same surface pattern as a surface pattern of the real material.

### CROSS REFERENCE TO RELATED APPLICATION

This application claims priority to and the benefit of Korean Patent Application No. 10-2019-0085052, filed Jul. 15, 2019, which is incorporated herein by reference in its entirety.

### FIELD

The present disclosure relates to a replica film of a real material, a method for producing the same, and an automotive part comprising the same.

### BACKGROUND

The statements in this section merely provide background information related to the present disclosure and may not constitute prior art.

Interior/exterior materials using highly expensive real carbon woven materials have been applied mainly to high-performance vehicles to improve the quality of automotive interior/exterior materials. However, the costs of real carbon materials are high and, when using these materials to manufacture parts, the processes are complicated.

Accordingly, there have been several attempts to copy real carbon such as forming a film having a shape similar to the surface pattern of real carbon through injection molding that uses a mold and coating the surface to be applied to parts.

These technologies have an advantage in terms of cost saving, but the quality of the external appearance is considerably low. A particular limitation includes the fact that copying technologies of the related art cannot implement a line width of real carbon and cannot implement the particular three-dimensional feeling and lustrous feeling.

The above information disclosed in this Background section is only for enhancement of understanding of the background of the present disclosure, and therefore it may contain information that does not form the prior art that is already known to a person of ordinary skill in the art.

### SUMMARY

The present disclosure provides a replica film displaying the particular characteristics of a real material by precisely copying the real material, and a method of producing the replica film.

The present disclosure also provides a replica film that can even be applied to automotive parts having complicated, non-flat shapes, and a method of producing the replica film.

The present disclosure improves the commercial value of a replica film by applying a color different from the color of a real material.

The present disclosure is not limited to what is described above. What the present disclosure provides will be clearer from the following description and will be accomplished through the means and combinations thereof described in the claims.

A replica film of a real material according to one form of the present disclosure includes a base material layer and a resin layer disposed on the base material layer. The resin layer has a first surface facing the base material layer and a second surface, opposite the first surface, having a same surface pattern as a surface pattern of the real material.

The base material layer may include at least one selected from the group of Polycarbonate (PC), Polymethylmethacrylate (PMMA), Polyethylene terephthalate (PET), and combinations thereof.

The thickness of the base material layer may be 0.125 mm to 0.5 mm.

The real material may include at least one selected from the group of real carbon, real wood, natural cork, real stone, thin metal, Hanji, and combinations thereof.

The surface pattern of the second surface may have grooves and ridges, in which the grooves may be formed 100 μm to 250 μm deep from the second surface.

The resin layer may include at least one selected from the group of urethane acrylate, acrylic acrylate, polyester acrylate, and combinations thereof.

The replica film may further include a deposition layer disposed on the resin layer and including at least any one of metal selected from the group of aluminum (Al), chromium (Cr), nickel-chromium (Ni—Cr), tin (Sn), and combinations thereof; and at least one ceramic selected from the group of titanium dioxide (TiO₂), silicon dioxide (SiO₂), and a combination thereof.

The deposition layer may be formed along the surface pattern of the second layer of the resin layer.

The transmittance of the base material layer may be 20% to 80%.

The replica film may further include a print layer disposed on the deposition layer and including at least one selected from the group of urethane-based ink, polyvinyl chloride-based ink, and a combination thereof.

A method of producing a replica film of a real material according to one form of the present disclosure includes: manufacturing a stamper including a surface pattern having a shape corresponding to a surface pattern of the real material; forming a resin layer having a first surface facing the base material layer and a second surface opposite the first surface on the base material layer; and forming a surface pattern, that is the same as the surface pattern of the real material, on the second surface using the stamper.

A stamper having a surface pattern with a shape corresponding to the surface pattern of the real material may be formed by plating metal on a surface of the real material and then removing the real material.

A surface pattern that is the same as the surface pattern of the real material may be formed on the second surface of the resin layer by winding the stamper around a roller and supplying the resin layer to the roller.

The method may further include forming a deposition layer disposed on the resin layer by depositing at least any one of metal selected from the group of aluminum (Al), chromium (Cr), nickel-chromium (Ni—Cr), tin (Sn), and combinations thereof; and at least one ceramic selected from the group of titanium dioxide (TiO₂), silicon dioxide (SiO₂), and a combination thereof along the surface pattern of the second surface of the resin layer.

The replica film may further include forming a print layer by printing at least one selected from the group of urethane-based ink, polyvinyl chloride-based ink, and a combination thereof on the deposition layer.

An automotive part according to one form of the present disclosure may include a base layer and the replica film disposed on the base layer.

A curvature of at least a portion of the base layer may be 0.5 or more.

According to the present disclosure, it is possible to achieve a replica film having the particular characteristics of a real material by precisely copying the real material.

According to the present disclosure, it is possible to achieve a replica film that has excellent formability and can even be applied to automotive parts having complicated non-flat shapes.

According to the present disclosure, it is possible to achieve a replica film that has an external appearance at the same level of a real material and has excellent price competitiveness because it can be manufactured at 1/10 the cost of the real material.

According to the present disclosure, it is possible to achieve a replica film that has a high commercial value because it implements a color different from that of a real material.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1A is a cross-sectional view schematically showing the structure of real carbon film;

FIG. 1B is a view showing a result of observing the surface pattern of the real carbon film of FIG. 1A using an optical microscope;

FIG. 2A is a cross-sectional view schematically showing a replica film of real carbon of the related art;

FIG. 2B is a view showing a result of observing the surface pattern of the real carbon film of FIG. 2A using an optical microscope;

FIG. 3 is a cross-sectional view schematically showing a replica film of one form of a real material according to the present disclosure;

FIG. 4 is a flowchart showing one form of a method of producing a replica film of a real material according to the present disclosure;

FIGS. 5A to 5C are reference views illustrating a step of manufacturing a stamp used in one form of a method of producing a replica film of a real material according to the present disclosure, in which FIG. 5A is a cross-sectional view showing a real material, FIG. 5B is a reference view showing a method of manufacturing a stamper using the real material, and FIG. 5C is a reference view showing a state when the real material and the stamper are separated;

FIG. 6 is a reference view illustrating a step in which a surface pattern, which is the same as the surface pattern of a real material, is applied on the surface of the resin layer using a stamper used to produce a replica film of one form of a real material according to the present disclosure;

FIG. 7 is a view showing a result of observing, using an optical microscope, the surface pattern of a replica film of a real material according to the present disclosure; and

FIGS. 8A to 8C are reference views schematically showing a method of manufacturing an automotive part according to the present disclosure in which FIG. 8A shows a step of putting a replica film into a mold, FIG. 8B shows a step of injecting a base resin to the rear surface of the replica film, and FIG. 8C shows a step of taking the automotive part out of the mold.

FIG. 9 is a view showing a replica film of a real material according to the present disclosure applied to an automotive part.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The above-mentioned objects of the present disclosure, other objects, features, and advantages would be easily understood through the following exemplary forms related to the accompanying drawings. The present disclosure is not limited to the forms described herein and may be implemented in other ways. The variations disclosed herein are provided so that the disclosed contents can be made thorough and complete and the spirit of the present disclosure can be sufficiently transmitted to those skilled in the art.

Similar reference numerals are assigned to similar components in the following description of drawings. In the accompanying drawings, the dimensions and structures are larger than the actual dimensions to make the present disclosure clear. Terms used in the specification—'first', ‘second’, etc.—may be used to describe various components, but the components are not to be construed as being limited to the terms. The terms are used only to distinguish one component from another component. For example, the ‘first’ component may be named the ‘second’ component, and vice versa, without departing from the scope of the present disclosure. Singular forms are intended to include plural forms unless the context clearly indicates otherwise.

It will be further understood that the terms “comprises” or “has” used in this specification, specify the presence of stated features, steps, operations, components, parts, or a combination thereof, but do not preclude the presence or addition of one or more other features, numerals, steps, operations, components, parts, or a combination thereof. When an element such as a layer, a film, a region, and a plate is “on” another component, it can either be directly on the other element or have other intervening elements therebetween. When an element such as a layer, a film, a region, and a plate is “beneath” another component, it can either be directly beneath the other element or have other intervening elements therebetween.

Unless stated otherwise, all the numerals, values, and/or expressions showing components, reaction conditions, and the amounts of polymer compositions and mixtures used herein are approximate quantities reflecting various uncertainties in measurement, which are generated when these numbers basically obtain these values from others, and therefore should be construed as being modified by a term “approximately”. Further, when a numeral range is disclosed herein, the range is continuous and includes all values from a minimum value to a maximum value including the maximum value in the range unless stated otherwise. Further, when this range indicates an integer number, all integer values from a minimum value to a maximum value including the maximum value are included unless stated otherwise.

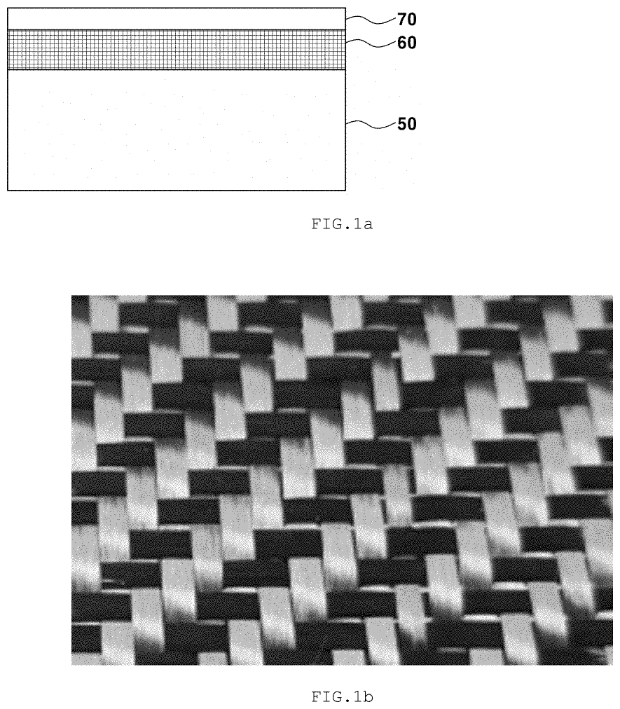

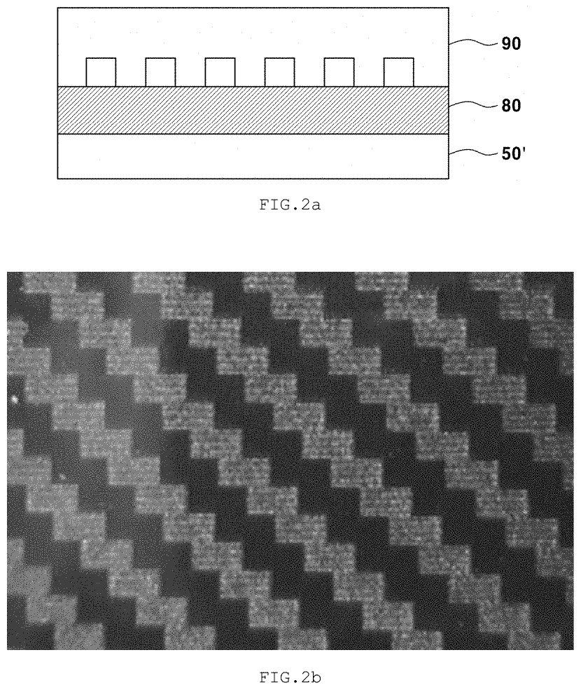

FIG. 1A is a cross-sectional view schematically showing the structure of real carbon film. Referring to FIG. 1A, the real carbon film includes a kind of support layer 50, a woven carbon fabric 60 disposed on the support layer 50, and a coating layer 70 disposed on the carbon fabric 60. Accordingly, the particular pattern of the carbon fabric 60 is exposed to the outside, as shown in FIG. 1b, thereby creating a certain aesthetic look.

FIG. 2A is a cross-sectional view schematically showing a replica film of real carbon of the related art. Referring to FIG. 2, the replica film of the related art includes a kind of support layer 50′, a black print layer 80 printed on the support layer, and a film layer 90 having a predetermined shape of surface pattern on the print layer. The color of the print layer 80 is exposed to the outside, depending on the surface pattern of the film layer 90. Accordingly, as shown in FIG. 2B, a pattern similar to the real carbon is exposed to the outside. The line width of the pattern of the real carbon film is about 5 μm, whereas the line width of the replica film of the related art is about 50 μm. That is, the line width of the replica film of the related art is too large thereby drastically deteriorating the quality of the external appearance compared to the real carbon film. This is because the pattern is implemented through the film layer 90 in the replica film in which the film layer 90 is manufactured through a mold, which creates physical limitation in reducing the embossed gaps.

Hereafter, a replica film of a real material according to the present disclosure is described in detail.

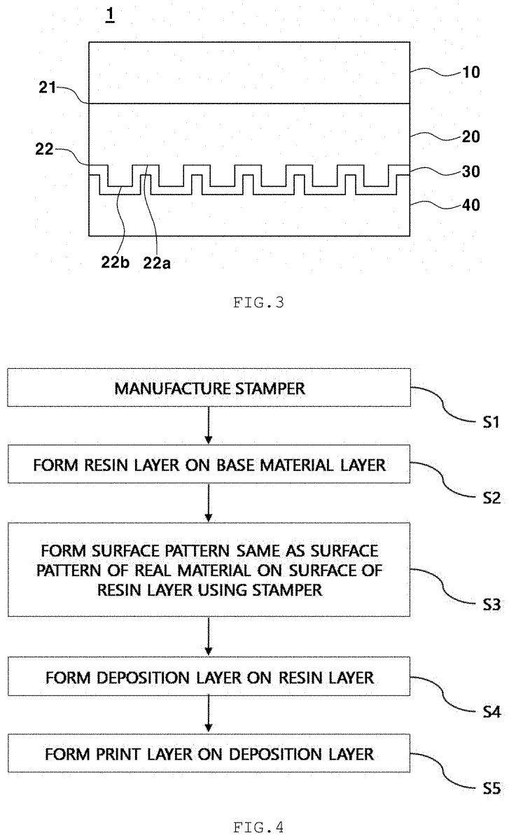

FIG. 3 is a cross-sectional view schematically showing a replica film 1 of a real material according to the present disclosure. Referring to FIG. 3, the replica film 1 may include: a base material layer 10; a resin layer 20, disposed on the base material layer 10 and having a first surface 21 facing the base material layer 10 and a second surface 22 opposite the first surface 21; a deposition layer 30 on the resin layer; and a print layer 40 disposed on the deposition layer.

The real material can be used without specific limitation as long as it has a particular surface texture. In detail, the real material may be selected from the group of real carbon, real wood, natural cork, real stone, thin metal, Hanji, and combinations thereof. Preferably, the real material may be real carbon. According to the present disclosure, it is possible to achieve a replica film having a surface pattern that is the same as the surface pattern of the real material and is exposed to the outside.

The base material layer 10 may include a transparent material, including but not limited to at least one material selected from the group of Polycarbonate (PC), Polymethylmethacrylate (PMMA), Polyethylene terephthalate (PET), and combinations thereof.

The thickness of the base material layer 10 may be 0.125 mm to 0.5 mm. Depth feeling of the replica film 1 may not be implemented when the thickness is less than 0.125 mm, and formability may be deteriorated when the thickness exceeds 0.5 mm.

The resin layer 20 may have the second surface 22 with a same surface pattern as the surface pattern of the real material. The method of forming the second surface 22 is described below. Although the surface pattern of the second surface 22 shown in FIG. 3 has an uneven structure, the surface pattern is not limited thereto and should be construed as being the same as the surface patterns of real materials selected in accordance with the purpose.

The surface pattern of the second surface 22 has grooves 22a and ridges 22b. The grooves 22a may be formed 100 μm to 250 μm deep from the second surface 22. The reference for measuring the depth of the grooves 22a may be the flat surfaces of the ridges 22b of the second surface 22. When the thickness is less than 100 μm, a three-dimensional feeling may not be achieved. On the other hand, when the thickness exceeds 250 μm, formability may be deteriorated and inconspicuousness from the print layer 40 may be deteriorated.

In the surface pattern of the second surface 22, the grooves 22a and ridges 22b may be shown alternating across each other. The gaps may be regular or irregular. The grooves 22a may be recessed vertically or close to verticality, or may be recessed at a predetermined angle from the ridges 22b, as shown in FIG. 3.

The resin layer 20 may be formed through UV curing, which will be described below. Accordingly, the resin layer 20 may include UV-curable resin. In detail, the resin layer 20 may include UV-curable resin selected from the group of urethane acrylate, acrylic acrylate, polyester acrylate, and combinations thereof.

The contents of the components contained in the resin layer 20 can be appropriately adjusted and mixed in accordance with the purpose, but the urethane acrylate may be included by 40 wt % to 70 wt % to secure an elongation when the replica film is applied to automotive parts.

It may be possible to adjust the molecular weight of each UV-curable resin included in the resin layer 20 or add a functional additive in consideration of the physicochemical properties, formability, pattern maintenance, etc., of the resin layer 20.

The deposition layer 30 is disposed on the resin layer and may be formed along the surface pattern of the second surface 22 of the resin layer 20 without damaging the surface pattern. The meaning of not damaging the surface pattern of the second surface 22 is that the deposition layer 30 is deposited in a very thin layer along the surface pattern and the surface of the deposition layer 30 is also formed substantially in the same shape as the surface pattern of the resin layer 20.

Luster of the replica film 1 is implemented in accordance with the deposition source contained in the deposition layer 30. In detail, the deposition layer 30 may include at least one metal selected from the group of aluminum (Al), chromium (Cr), nickel-chromium (Ni—Cr), tin (Sn), and combinations thereof; and at least one ceramic selected from the group of titanium dioxide (TiO₂), silicon dioxide (SiO₂), and a combination thereof.

Further, the color of the replica film 1 depends on the deposition source that is used when the deposition layer 30 is formed. The color that is revealed by the deposition source interacts with the color of the print layer 40, thereby implementing new color and saturation not implemented from real carbon.

The transmittance of the deposition layer 30 may be 20% to 80%. When the transmittance is less than 20%, the deposition layer 30 is formed too thick, in which case the color of the print layer 40 may not be revealed to the outside. On the other hand, when the transmittance exceeds 80%, the deposition layer 30 is too transparent, in which case luster may not be implemented.

The print layer 40 is a component that is disposed on the deposition layer 30, implementing the general color of the entire replica film 1 and protecting both the resin layer 20 and the deposition layer 30.

The print layer 40 is not limited thereto and may be formed by printing ink, which is selected from the group of urethane-based ink, polyvinyl chloride-based ink, and a combination thereof, on the deposition layer with a predetermined degree.

The ink may be a mono-fluid type or bi-fluid type ink. When it is a bi-fluid type ink, isocyanate-based curing agents such as HDI, MDI, TDI, and IPDI may be used as a curing agent and the content may be 10 wt % to 20 wt % of the entire weight of the ink composition. When the content of the curing agent is less than 10 wt %, the properties of the print layer 20 are deteriorated and thus ink wash-out may occur, whereas when the content exceeds 20 wt %, printability may be deteriorated.

When the print layer 40 is formed, the degree is not specifically limited, but may be 4 degrees or more in printing. When the print layer 40 is printed less than 4 degrees, ink wash-out may occur when the replica film 1 is applied to automotive parts.

Hereafter, a method for producing a replica film of a real material according to the present disclosure is described in detail.

FIG. 4 is a flowchart showing one form of a method of producing a replica film of a real material according to the present disclosure. Referring to FIG. 4, the method may include: manufacturing a stamper including a surface pattern having a shape corresponding to the surface pattern of a real material (S1); forming a resin layer on a base material layer (S2); forming a surface pattern, that is the same as the surface pattern of the real material, on a second surface of the resin layer using the stamper (S3); forming a deposition layer on the resin layer (S4); and forming a print layer on the deposition layer (S5).

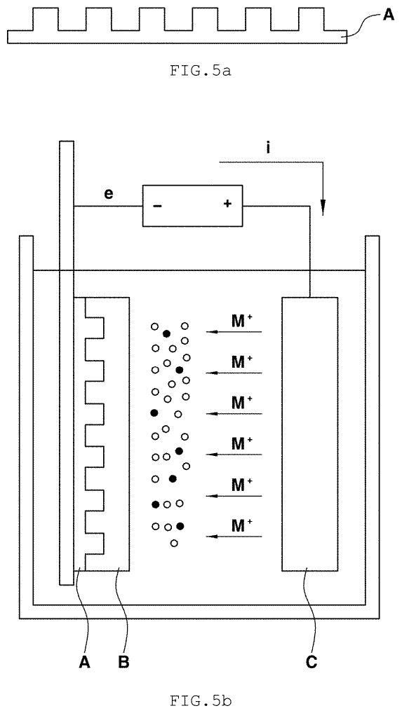

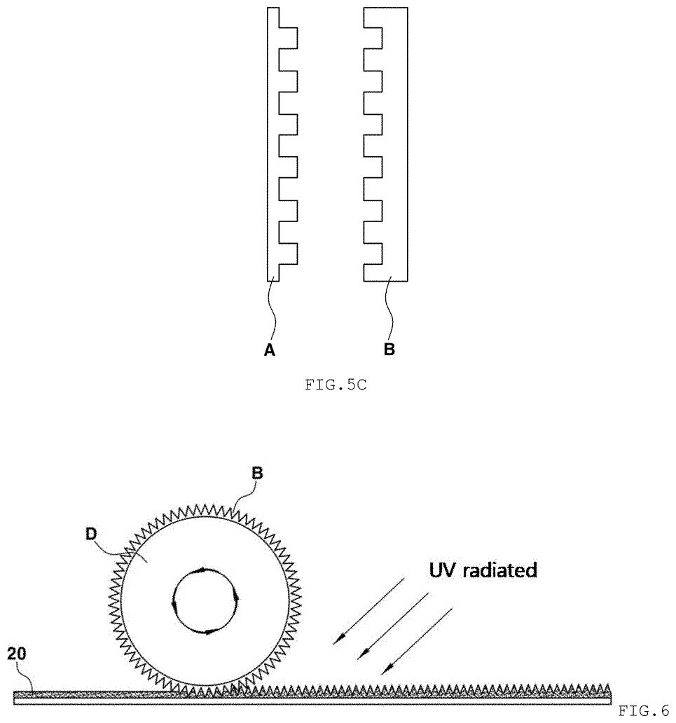

FIGS. 5A to 5C are reference views illustrating the manufacturing of a stamper (S1). Simply, FIG. 5A is a cross-sectional view showing a real material A, FIG. 5B is a reference view showing a method of manufacturing a stamper B using the real material A, and FIG. 5C is a reference view showing a state when the real material A and the stamper B are separated.

First, as shown in FIG. 5A, a real material A having a specific surface pattern is prepared. Thereafter, a stamper B can be formed through electro-forming using the real material A, as shown in FIG. 5B. In detail, a stamper B having a predetermined thickness can be obtained by electrolyzing metal C such that metal ions (M⁺) are attached (plated) to the surface pattern of the real material A. The thickness of the stamper B is not specifically limited and can be appropriately adjusted in accordance with the purpose. When the real material A and the stamper B are separated, as shown in FIG. 5C, a stamper B having a surface pattern having a shape corresponding to the surface pattern of the real material A can be obtained.

A resin layer can be formed by applying UV-curable resin on the base material layer described above with a predetermined thickness (S2). The resin layer in this state does not have a surface pattern.

FIG. 6 is a reference view illustrating the forming of a surface pattern, which is the same as the surface pattern of the real material, on the resin layer using the stamper B (S3).

Referring to FIG. 6, the stamper B obtained as described above is wound around a roller D and the resin layer 20 is supplied to the roller D that is rotating such that the stamper B wound around the roller D presses the resin layer 20. Accordingly, the surface pattern of the stamper B is transcribed to the surface of the resin layer 20. As a result, a surface pattern that is the same as the surface pattern of the real material is formed on the surface of the resin layer 20.

At the same time or a different time, an ultraviolet ray is radiated to the resin layer to cure the resin layer so that the surface layer formed on the resin layer is not destroyed. The radiation manner, position and intensity of the ultraviolet ray are not specifically limited and can be appropriately adjusted.

After a surface pattern is formed on the resin layer as described above, a deposition layer can be formed on the resin layer (S4). The method of forming the deposition layer is not specifically limited, but it may be possible to form the deposition layer by depositing a deposition source described above in a vacuum chamber or by using roll-to-roll deposition, atmospheric pressure deposition, etc.

Thereafter, a print layer can be formed on the deposition layer (S5). The method of forming the print layer is not specifically limited but screen printing may be used.

FIG. 7 shows a result of observing the surface of a replica film manufactured by the method described above using an optical microscope. Comparing a surface pattern of real carbon (FIG. 1B) with FIG. 7, it can be seen that the replica film according to the present disclosure shows a pattern having substantially the same shape as the real carbon shown outside. Further, comparing a replica film of the related art (FIG. 2B) with FIG. 7, it can be seen that the replica film of the present disclosure shows luster and depth feeling that are more similar to those of the real carbon compared to the replica film of the related art.

An automotive part according to the present disclosure may include a base layer and the replica film disposed on the base layer.

The method of manufacturing the automotive part is not specifically limited, but insert injection may be used.

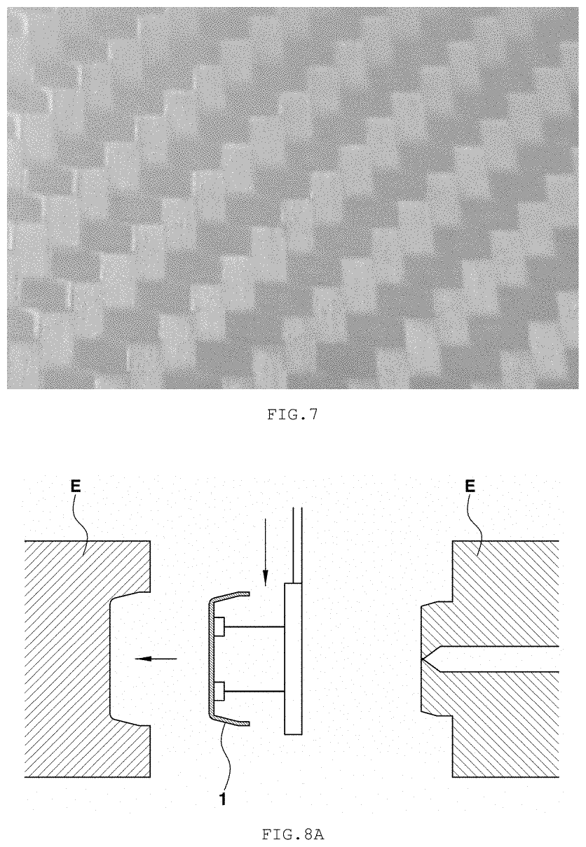

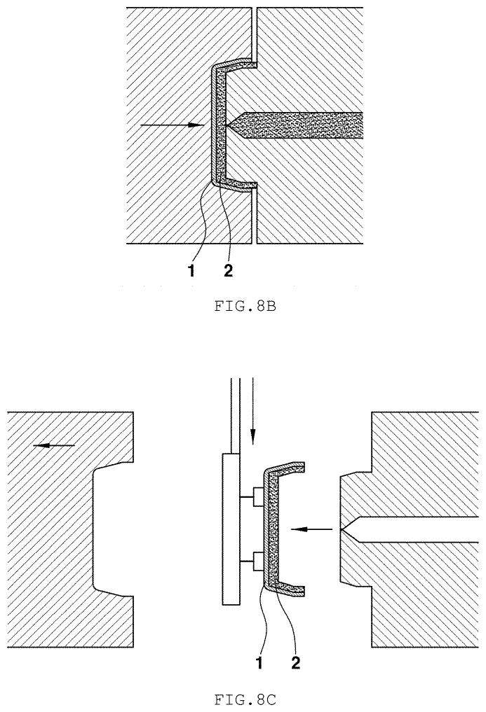

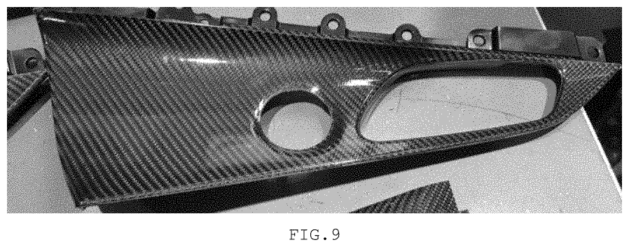

FIGS. 8A to 8C are reference views schematically showing a method of manufacturing an automotive part according to the present disclosure. In detail, the replica film 1 described above is put into a mold E, as shown in FIG. 8A, and a base resin is injected to the rear surface of the replica film 1, as shown in FIG. 8B, thereby forming a base layer 2. Thereafter, the replica film 1 and the base layer 2 are taken out of the mold E, as shown in FIG. 8C, thereby being able to obtain an automotive part.

Before putting the replica film 1 into the mold E, it is possible to pre-heat the replica film 1, perform thermal press forming or vacuum forming to make the shape of the part, and then perform trimming.

The base resin is not specifically limited, but may include at least one selected from the group of Acrylonitrile butadiene styrene (ABS), polycarbonate, and a combination thereof.

Further, it can be seen that the base layer has a curvature of 0.5 or more at at least any one portion, specifically, at the end. The replica film according to the present disclosure can even be applied to automotive parts having complicated non-flat shapes.

FIG. 9 is a view showing a replica film of a material according to the present disclosure applied to an automotive part. The automotive part may be a door garnish, as shown in FIG. 9, a center garnish, a roof, a hood, etc.

While this present disclosure has been described in connection with what is presently considered to be practical exemplary forms, it is to be understood that the present disclosure is not limited to the disclosed forms, but, on the contrary, it is intended to cover various modification and equivalent arrangements included within the spirt and cope of the present disclosure.

1. A replica film of a real material, comprising:
a base material layer; and
a resin layer disposed on the base material layer,
wherein the resin layer has a first surface facing the base material layer and a second surface opposite the first surface,
wherein the second surface has a same surface pattern as a surface pattern of the real material.

2. The replica film of claim 1, wherein the base material layer includes at least one selected from a group of Polycarbonate (PC), Polymethylmethacrylate (PMMA), Polyethylene terephthalate (PET), and combinations thereof.

3. The replica film of claim 1, wherein the base material layer has a thickness of 0.125 to 0.5 mm.

4. The replica film of claim 1, wherein the real material includes at least one selected from a group of real carbon, real wood, natural cork, real stone, thin metal, Hanji, and combinations thereof.

5. The replica film of claim 1, wherein the surface pattern of the second surface has grooves and ridges, and
the grooves are formed 100 μm to 250 μm deep from the second surface.

6. The replica film of claim 1, wherein the resin layer includes at least one selected from a group of urethane acrylate, acrylic acrylate, polyester acrylate, and combinations thereof.

7. The replica film of claim 1, further comprising a deposition layer disposed on the resin layer and including at least any one of metal selected from a group of aluminum (Al), chromium (Cr), nickel-chromium (Ni—Cr), tin (Sn), and combinations thereof; and ceramic selected from a group of titanium dioxide (TiO₂), silicon dioxide (SiO₂), and a combination thereof.

8. The replica film of claim 7, wherein the deposition layer is formed along the surface pattern of the second layer of the resin layer.

9. The replica film of claim 7, wherein transmittance of the base material layer is 20% to 80%.

10. The replica film of claim 7, further comprising a print layer disposed on the deposition layer and including at least one selected from a group of urethane-based ink, polyvinyl chloride-based ink, and a combination thereof.

11. A method of producing a replica film of a real material, comprising:
manufacturing a stamper including a surface pattern having a shape corresponding to a surface pattern of the real material;
forming a resin layer having a first surface facing the base material layer and a second surface opposite the first surface on the base material layer; and
forming a surface pattern, that is the same as the surface pattern of the real material, on the second surface using the stamper.

12. The method of claim 11, wherein a stamper having a surface pattern having a shape corresponding to the surface pattern of the real material by plating metal on a surface of the real material and then removing the real material is formed.

13. The method of claim 11, wherein the real material includes at least one selected from a group of real carbon, real wood, natural cork, real stone, thin metal, Hanji, and combinations thereof.

14. The method of claim 11, wherein the base material layer includes at least one selected from a group of Polycarbonate (PC), Polymethylmethacrylate (PMMA), Polyethylene terephthalate (PET), and combinations thereof.

15. The method of claim 11, wherein the resin layer includes at least one selected from a group of urethane acrylate, acrylic acrylate, polyester acrylate, and combinations thereof.

16. The method of claim 11, wherein a surface pattern that is the same as the surface pattern of the real material is formed on the second surface of the resin layer by winding the stamper around a roller and supplying the resin layer to the roller.

17. The method of claim 11, further comprising forming a deposition layer disposed along the surface pattern of the second surface of the resin layer by depositing at least any one of metal selected from a group of aluminum (Al), chromium (Cr), nickel-chromium (Ni—Cr), tin (Sn), and combinations thereof; and ceramic selected from a group of titanium dioxide (TiO₂), silicon dioxide (SiO₂), and a combination thereof.

18. The method of claim 17, wherein transmittance of the base material layer is 20% to 80%.

19. The method of claim 11, further comprising forming a print layer on a deposition layer by printing at least one selected from a group of urethane-based ink, polyvinyl chloride-based ink, and a combination thereof.

20. An automotive part comprising:
a baser layer having a predetermined shape; and
the replica film of claim 1 disposed on the base layer,
wherein a curvature of at least a portion of the base layer is 0.5 or more.
